(19) United States
(12) Patent Application Publication
(10) Pub. No.: US 2007/0031996 A1
(43) Pub. Date: Feb. 8, 2007

(54) Packaged integrated circuit having a heat spreader and method therefor

(76) Inventors: Sheila F. Chopin, Austin, TX (US); Peter R. Harper, Lucas, TX (US); Jose Montes De Oca, New Braunfels, TX (US); Kim Heng Tan, Satu (MY); Lan Chu Han, Klang (MY)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 10/553,529

(22) PCT Filed: Apr. 16, 2004
(86) PCT No.: PCT/US04/11873

§ 371 Date: Aug. 22, 2006

(30) Foreign Application Priority Data
Apr. 26, 2003 (MY) P120031587

(51) Int. Cl. H01L 21/00

(52) U.S. Cl. 438/122; 438/121; 438/123; 438/124; 438/113

(57) ABSTRACT

An integrated circuit is packaged, in one embodiment, by wire bonding to pads supported by tape. The tape also supports traces that run from the wire bonded location to a pad for solder balls. A heat spreader is thermally connected to the integrated circuit and is located not just in the area under the die but also extends to the edge of the package in the area outside the wire bonding location. This outer area is thermally connected to the area under the die by thermal bars that run between some of the wire bond locations. During the manufacturing of the package the heat spreader is connected to slotted rails by tie bars. During singulation, the tie bars are easily broken or sawed because they are significantly reduced in thickness from the thickness of the heat spreader as a whole.

### FIELD OF THE INVENTION

This invention relates to packaged integrated circuits, and more particularly, to integrated circuits that have heat spreaders to dissipate heat generated during the operation of the integrated circuit.

### RELATED ART

Integrated circuits, especially complex ones, sometimes generate sufficient amounts of heat that require special treatment. Typically, the heat increases as the speed of operation increases. Thus, as speeds increase the heat problem increases. This is often exacerbated by the desire to decrease package sizes. Thus, there is pressure to dissipate increased amounts of heat without increasing package size. An extra measure frequently taken is to provide some type of heat sink. Ultimately the heat must be transferred to the ambient atmosphere but the rate of this transmission of heat is the primary measure of success of the heat sink. The intent is to spread the heat generated by the integrated circuit as quickly as possible to the ambient. Thus, the continuing challenge is to provide a package that effectively dissipates heat with a package constrained by size and electronic performance.

### BRIEF DESCRIPTION OF THE DRAWINGS

The present invention is illustrated by way of example and not limited by the accompanying figures, in which like references indicate similar elements, and in which:

FIG. 1 is flow chart of a method of making a packaged integrated circuit according to an embodiment of the invention;

FIG. 2 is a top view of a packaged integrated made according to the method of FIG. 1;

FIG. 3 is a cross section of the packaged integrated circuit of FIG. 2 taken at one location;

FIG. 4 is a cross section of a portion of the packaged integrated circuit of FIG. 2 taken at another location;

FIG. 5 is a top view of a packaged integrated circuit according to another embodiment of the invention;

FIG. 6 is a side view of the packaged integrated circuit of FIG. 6.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION OF THE DRAWINGS

An integrated circuit is packaged, in one embodiment, by wire bonding to pads supported by tape. The tape also supports traces that run from the wire bonded location to a pad for solder balls. A heat spreader is thermally connected to the integrated circuit and is located not just in the area under the die but also extends to the edge of the package in the area outside the wire bonding location. This outer area is thermally connected to the area under the die by thermal bars that run between some of the wire bond locations. During the manufacturing of the package the heat spreader is connected to slotted rails by tie bars. During singulation, the tie bars are easily broken or sawn because they are significantly reduced in thickness from the thickness of the heat spreader as a whole. This is better understood by reference to the drawings and the following description.

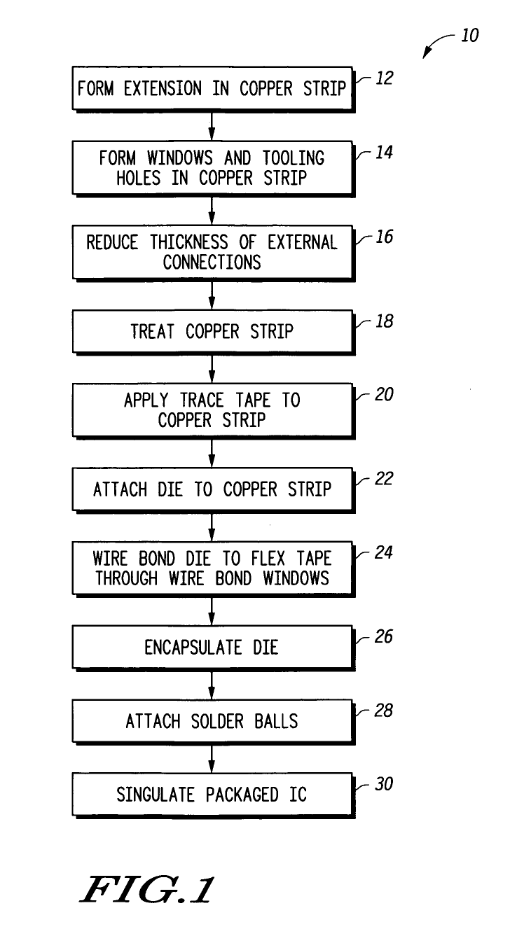

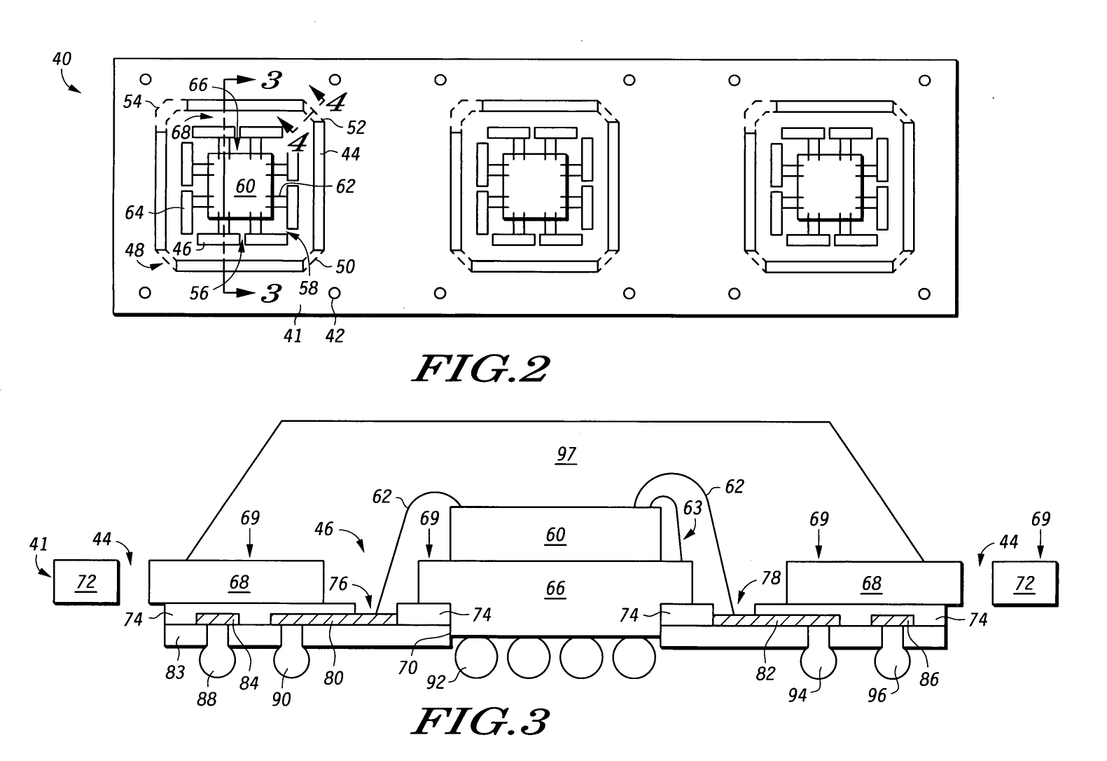

Shown in FIG. 1 is a flow chart of a method 10 comprising steps 12, 14, 16, 18, 20, 22, 24, 26, 28, and 30 for making a packaged integrated circuit (IC) 40 shown in FIG. 2. Packaged IC 40 comprises a copper strip 41, tooling holes 42 along both edges of copper strip 41, singulation slots 44, wire bond windows 46, tie bars 48, 50, 52, and 54, thermal bars 56 and 58, integrated circuit 60, wire bonds 62, contacts 64, inner area 66, and outer area 68. Shown in the cross section of FIG. 3 are features of packaged IC 40 not shown in the top view of FIG. 2. Shown in FIG. 3 are copper strip 41 comprising a heat spreader 69 having portions in inner area 66 and outer area 68 and having portions 72 outside singulation slots 44, an extension 70 of heat spreader 69 in inner area 66, a solder mask 74 having openings 76 and 78, metal traces 80, 82, 84, and 86, solder balls 88, 90, 92, 94, and 96, and encapsulant 97, and tape 83 for supporting traces 80, 82, 84, and 86. Solder balls 92 are connected to the extension 70 of heat spreader 69. Wires 62 provide wire bonding between IC 60 and traces 80 and 82 at the openings 76 and 78 in solder mask 74. Openings 76 and 78 are in wire bond windows 46. Wire 63 connects IC 60 to heat spreader 69.

Packaged IC 40 has the heat spreader 69 not just in the inner area 66 but also in the outer area 68. The outer area portion 68 is thermally connected to the inner area portion 66 by thermal bars 56 and 58. Heat spreader 69 being in the outer area 68 provides a substantial increase in heat dissipation, which is a significant benefit. There are a total of 8 thermal bars shown in this example for providing thermal coupling between the inner area portion 66 of the heat spreader and the outer area portion 68. This provides more thermal coupling between the inner portion 66 and the outer portion 68 than if only the four thermal bars 58, the ones at the corners, were used. It may be beneficial to use even more than eight thermal bars. On the other hand, there may be situations in which just the four thermal bars 58 are sufficient. In such case each of wire bond windows 46 would extend along the whole side of the die. In the example shown, using eight thermal bars, each wire bond window extends for only about half the side of the die.

Solder balls 92 are preferably for providing a ground connection to IC 60 by way of heat spreader 69. The extension 70 of heat spreader 69 is for providing an even height for solder balls 92 with solder balls 88, 90, 94, and 96. In FIG. 3, extension 70 is shown as being below tape 83. Although tape 83 is thin, the punch holes that penetrate tape 83 for making connection between solder balls 88, 90, 94, and 96 to consume some solder. The extension 70 is chosen to be of a height that results in solder balls 88-96 are all on the same plane. Solder balls 92 are preferably attached by contact pads present on extension 70 and otherwise covering extension with a thin dielectric such as black oxide, which could easily be about 100 Angstroms. This is a negligible thickness compared to the thickness of tape 83. The contact pads could be any solderable surface such as nickel/gold, palladium, and silver. The plurality of solder balls 92, in addition to providing for an excellent ground contact, also provides additional thermal dissipation for IC 60 by transferring additional heat from heat spreader 69.

Shown in FIG. 4 is a cross section taken at tie bar 52, which shows that tie bar 52 has a reduced thickness from the thickness of heat spreader 69. FIG. 4 shows the portion of heat spreader 69 at outer area 68 and portion 72 outside singulation slots 44 with tie bar 52 therebetween to maintain structural strength between the area outside the singulation slots 44 and the inner area. As shown in FIG. 3, encapsulation 97 extends to just short of the singulation slots. The singulation slots are the boundary of a completed packaged IC.

As shown in step 12 of FIG. 1, extension 70 is formed in a beginning copper strip 41. Copper is generally preferable but other suitable materials, especially ones that have good thermal conductivity, could also be used. Extension 70, which can be considered a pedestal, can be formed by using a mask to protect extension 70 during an etch step. The remaining copper thickness may be about 500 microns and the extension 70 about an additional 120 microns in thickness. Windows, holes, and slots are then formed by etching. The reduced thickness of tie bars 56 and 58 can also be performed in the same etching step by masking one side of copper strip 41 where the thickness is to be reduced. In such case, steps 14 and 16 can be performed in the same step. Windows, holes, and slots may also be formed by punching them out. In such case, steps 14 and 16 would not be combined. Also, the reduced thickness at tie bars 56 and 58 can be achieved by stamping, coining, or other means.

Copper strip 41 is then treated to prepare it for additional layers. This is a conventional step known to those of ordinary skill in the art in preparation for receiving a flex tape. The flex tape is then attached to copper strip 41. The flex tape includes all of the layers 74, 76, and 83 already patterned. Conventional materials may be used for the flex tape and it may be attached in any manner to copper strip 41. The overall thickness of the flex tape in this example is about 145 microns with the thickness of the tape at about 75 microns, the adhesive at about 25 microns, and the copper traces at about 30 microns, and the solder mask at about 15 microns. These elements are held together by conventional means. After such conventional attachment, IC 60, a semiconductor die, is attached to copper trace 41 in the middle, which is in area 66, as shown in step 22. Wire bonding is then performed as shown in step 24 to electrically attach IC 60 to traces supported by tape 83. As shown in step 26, encapsulant is applied over IC 60. This is conventionally achieved by molding, but any other means could also be used. As shown in step 28 the solder balls are then applied. Then as shown in step 30, the various packaged ICs are singulated. This singulation step is aided by the reduced thickness at tie bars 48-54. Singulation by punching out is an effective technique.

An alternative is to singulate by sawing. Sawing is also aided by having the reduced thickness for tie bars 48-54. Punching in particular has been found to be difficult with existing equipment of tie bars that are 500 microns thick. Punching has been found to be effective for thicknesses less than 250 microns. Thus tie bars 48-54 are preferably not greater than 250 microns. Sawing of copper presents difficulties as well because the copper tends to collect on the saw blades, and this aspect increases significantly with thicker copper. Additional types of cutting, e.g., high pressure water jet, may also be used and benefit from the reduced thickness. Thus the reduced thickness is significant in reducing problems associated with severing the heat spreader from the portion outside the package perimeter.

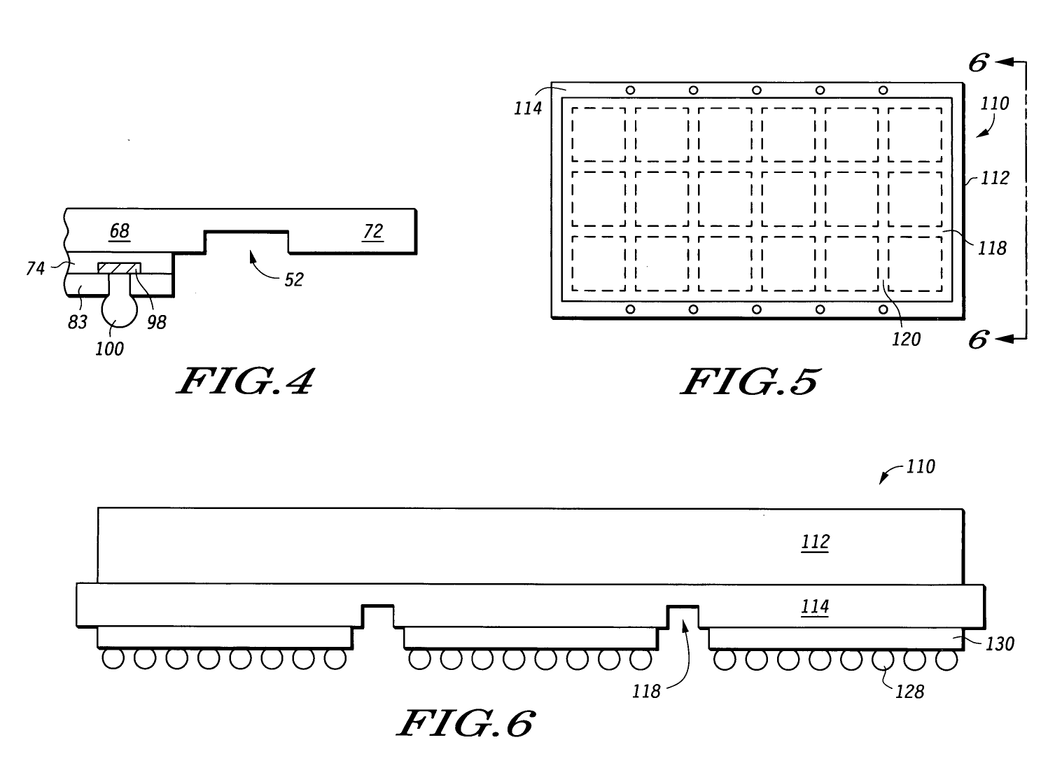

Shown in FIGS. 5 and 6 is an array of encapsulated die 112 attached to heat spreader 114 having saw street grids 118 of reduced thickness. Each of the encapsulated die has under it an array of solder balls 128 that are electrically connected to it via layer 130. The reduced thickness of saw street grids 118 provides for improved ease of cutting the heat spreader to singulate the die. This is analogous to the reduced thickness of tie bars 48-54 of packaged IC 40 of FIGS. 1-4. By having saw street grids 118 at a thickness that is not greater than about half the thickness of heat spreader 114 shown in FIG. 6 between solder balls 128 and encapsulated die 112. In this example, the heat spreader 114 is continuous around each packaged die instead of just at the corners. Thus, cutting must occur completely around each die and not just at the corners. Both FIGS. 1-4 and FIGS. 5-6 show examples of a die-up configuration, which is the case in which the die is on the opposite side as the solder balls. As an alternative, the die can be in a cavity on the same side as the solder balls and would still benefit from having a reduced thickness in the heat shield in the areas at the package edge for aiding in singulation.

In the foregoing specification, the invention has been described with reference to specific embodiments. However, one of ordinary skill in the art appreciates that various modifications and changes can be made without departing from the scope of the present invention as set forth in the claims below. For example, there may be situations in which the extension of the heat spreader could be in a location other than directly under the die. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

1. A method for making a packaged integrated circuit (IC) comprising:
forming a heat spreader in a sheet of thermally conductive material;
attaching an IC die in a die up configuration to the heat spreader at a first location of the heat spreader;
singulating the heat spreader with the attached IC die from a remaining portion of the sheet wherein the heat spreader extends to at least a portion of an edge of the packaged IC.

2. The method of claim 1 wherein the forming the heat spreader further includes:
forming a plurality of wire bond windows in the heat spreader located between the first location and an outer portion of the heat spreader.

3. The method of claim 2 wherein forming the wire bond windows further includes forming at least five thermal connection structures thermally coupling the first portion of the heat spreader with the outer portion of the heat spreader, each thermal connection structure defining at least a portion of a wire bond window of the plurality of wire bond windows.

4. The method of claim 1 wherein the forming the heat spreader further includes forming singulation slots in the sheet around an outer portion of the heat spreader, at least portions of the singulation slots being defined by portions of an edge of the outer portion of the heat spreader.

5. The method of claim 1 further comprising:
reducing the thickness of the sheet at a location at an edge of the heat spreader;
wherein the singulating the heat spreader with the attached IC die from a remaining portion of the sheet further includes cutting the sheet at the location at the edge of the outer portion.

6. The method of claim 1 further comprising:
encapsulating the IC die attached to the heat spreader, the encapsulating further including placing a mold die against the sheet including against the heat spreader at a location near the edge of the heat spreader.

7. A packaged integrated circuit (IC) comprising:
an IC die;
a heat spreader, the IC die thermally coupled to the heat spreader at a first location of the heat spreader in a die up configuration, the heat spreader extends to at least a portion of an edge of the packaged IC.

8. The packaged IC of claim 7 wherein the heat spreader defines a wire bond window located between the first location and an outer portion of the heat spreader.

9. The packaged IC of claim 8 further comprising:
a wire bond extending from a die bond pad on the IC die into the wire bond window to a wire bond finger.

10.-14. (canceled)

15. A method for making a packaged integrated circuit (IC) comprising:
forming a heat spreader in a sheet of thermally conductive material, wherein the forming includes reducing the thickness of the sheet at a location at an edge of the heat spreader;
attaching an IC die to the heat spreader at a first location of the heat spreader;
singulating the heat spreader with the attached IC die from a remaining portion of the sheet, wherein the singulating further includes cutting the sheet at the location at the edge of the heat spreader.

16. The method of claim 15 wherein the reducing the thickness of the sheet further includes etching a portion of the sheet at the location at the edge.

17. The method of claim 16 wherein the etching a portion of the sheet further includes etching a first planar side of the sheet at the location and not a second planar side of the sheet at the location, wherein the first planar side is opposite the second planar side.

18. The method of claim 17 wherein the die is attached to the heat spreader at a second planar side of the sheet.

19. The method of claim 15 wherein the reducing the thickness of the sheet further includes coining a portion of the sheet at the location at the edge.

20. The method of claim 15 wherein the forming a heat spreader further includes forming a first singulation slot in the sheet and forming a second singulation slot in the sheet generally orthogonal with respect to the first singulation slot, wherein the location extends from the first singulation slot to the second singulation slot.

21. The method of claim 15 wherein the edge of the heat spreader includes four sides, wherein the location at the edge of the heat spreader is located along at least a majority of a side of the four sides.

22. The method of claim 15 wherein:
the forming a heat spreader in the sheet further includes forming a plurality of heat spreaders in the sheet;
wherein the reducing the thickness of the sheet at a location at an edge of the heat spreader further includes reducing the thickness of the sheet at a plurality of locations with each location of the plurality at an edge of two adjacent heat spreaders of the plurality of heat spreaders;
wherein the attaching an IC die to the heat spreader further includes attaching each of a plurality of IC die to each of the plurality of heat spreaders at a first location of the each of the heat spreader;
encapsulating at least a portion of a first side of the sheet including encapsulating the plurality of IC dies in an encapsulate;
wherein the singulating the heat spreader with the attached IC die from a remaining portion of the sheet further includes singulating the plurality of heat spreaders with an attached IC die of the plurality of IC die, wherein the cutting the sheet at the location at the edge of the heat spreader further includes cutting the sheet of at the plurality of locations and cutting the encapsulate at locations above the plurality of locations.

23. The method of claim 15 wherein the location is at a corner of the heat spreader.

24. The method of claim 23 wherein the reducing the thickness of the sheet at the location at the edge of the heat spreader further includes reducing the thickness of the sheet at a plurality of locations at the edge wherein each location of the plurality is at a corner of the heat spreader.

25. The method of claim 15 wherein:
the sheet has a strip form, the strip form having a length and a width;
the forming a heat spreader in a sheet further includes forming a plurality of heat spreaders in the sheet along the length of the sheet in a one deep configuration along the width.

26.-39. (canceled)
